(19) United States
(12) Patent Application Publication
(10) Pub. No.: US 2026/0361507 A1
(43) Pub. Date: Nov. 12, 2026

(54) RADIO FREQUENCY CIRCUIT AND COMMUNICATION DEVICE

(71) Applicant: Murata Manufacturing Co., Ltd., Nagaokakyo-shi (JP)

(72) Inventor: Keisuke ARIMA, Nagaokakyo-shi (JP)

(73) Assignee: Murata Manufacturing Co., Ltd., Nagaokakyo-shi (JP)

(21) Appl. No.: 19/723,036

(22) Filed: Jun. 29, 2026

Related U.S. Application Data
(63) Continuation of application No. PCT/JP2024/042847, filed on Dec. 4, 2024.

(30) Foreign Application Priority Data
Jan. 24, 2024 (JP) 2024-008780

(51) Int. Cl. H04L 5/14

(52) U.S. Cl. CPC H04L 5/14

(57) ABSTRACT

A radio frequency circuit includes a first transmission filter having a pass band including a transmission band of a band, which is a frequency division duplex (FDD) band; a second transmission filter having a pass band including the transmission band of the band; a reception filter having a pass band including a reception band of the band; and a combiner. The combiner includes a first terminal connected to an antenna connection terminal, a second terminal connected to an output end of the first transmission filter, and a third terminal connected to an output end of the second transmission filter and an input end of the reception filter.

### CROSS-REFERENCE TO RELATED APPLICATIONS

This application is a U.S. continuation application filed under 35 U.S.C. § 111(a), claiming the benefit of priority under 35 U.S.C. § 120 of International Patent Application No. PCT/JP 2024/042847, filed on Dec. 4,2024, which claims the benefit of priority under 35 U.S.C. §119(a) to Japanese Patent Application No. 2024-008780, filed on Jan. 24, 2024. The entire contents of each of the above-referenced applications are hereby incorporated by reference.

### TECHNICAL FIELD

The present disclosure relates to a radio frequency circuit and a communication device.

### BACKGROUND ART

In Third Generation Partnership Project (3GPP) (registered trademark), it is being considered to apply a power class (for example, power class 2) that allows a higher maximum output power than previously allowed, to a frequency division duplex (FDD) band. Patent Document 1 discloses a radio frequency circuit that combines two radio frequency signals respectively amplified by two power amplifiers to support a power class allowing a higher maximum output power.

### CITATION LIST

### Patent Document

Patent Document 1: International Publication No. 2022/138001

### SUMMARY

According to an aspect of the present disclosure, a radio frequency circuit includes a first transmission filter with a pass band including a transmission band of an FDD band; a second transmission filter with a pass band including the transmission band of the FDD band; a third reception filter with a pass band including a reception band of the FDD band; and a combiner including a first terminal connected to an antenna connection terminal, a second terminal connected to the output end of the first transmission filter, and a third terminal connected to the output end of the second transmission filter and the input end of the third reception filter.

According to an aspect of the present disclosure, a communication device includes a signal processing circuit that processes a radio frequency signal and the radio frequency circuit that transmits the radio frequency signal between the signal processing circuit and an antenna.

The present disclosure is directed to suppressing degradation of receiver performance in an FDD band.

### BRIEF DESCRIPTION OF DRAWINGS

FIG. 1 is a circuit diagram of a communication device according to a first embodiment.

FIG. 2 is a circuit diagram of a first example of a combiner according to the first embodiment.

FIG. 3 is a circuit diagram of a second example of a combiner according to the first embodiment.

FIG. 4 is a circuit diagram of a communication device according to a second embodiment.

FIG. 5 is a circuit diagram of a communication device according to a variation of the second embodiment.

FIG. 6 is a circuit diagram of a communication device according to a third embodiment.

FIG. 7 is a diagram illustrating a transmission path and a reception path of the communication device of the third embodiment in a first mode.

FIG. 8 is a diagram illustrating a transmission path and a reception path of the communication device of the third embodiment in a second mode.

### Description of Embodiments

Patent Document 1 discloses a radio frequency circuit that combines two radio frequency signals respectively amplified by two power amplifiers to support a power class allowing a higher maximum output power. However, with the radio frequency circuit technology described above, the receiver performance in the FDD band may be degraded.

In view of the above, embodiments of the present disclosure provide a radio frequency circuit and a communication device that can suppress degradation of receiver performance in an FDD band. Specifically, a combiner is provided that includes a first terminal connected to an antenna connection terminal, a second terminal connected to an output end of a first transmission filter, and a third terminal connected to both an output end of a second transmission filter and an input end of a third reception filter. By connecting the third reception filter to the third terminal rather than directly to the antenna connection terminal, the third reception filter is placed on the transmission path that carries a lower power level, thereby suppressing the leakage of a transmission signal into the reception path and suppressing degradation of receiver performance.

Embodiments of the present disclosure are described in detail below with reference to the drawings. Each of the embodiments described below represents a general or specific example. Values, shapes, materials, components, and layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. The drawings schematically depict the functional arrangements of the circuit architecture to facilitate comprehension of the present disclosure. One skilled in the art will readily appreciate that the relative scales, physical aspect ratios, and spatial geometries may be adapted or varied to suit specific implementation environments without departing from the scope of the disclosure. The same reference number is assigned to substantially the same components in the drawings, and repeated descriptions of those components may be omitted or simplified.

In the descriptions of circuit configurations below, “connected” not only indicates that circuit elements are directly connected to each other with a connection terminal and/or a wire conductor but also indicates that the circuit elements are electrically connected to each other via another circuit element. “A is switchably connected to B” means that A and B can be connected and disconnected, that is, A is connected via a switch to B. Here, “A is connected to B” encompasses “A is switchably connected to B”. “C is connected between A and B” indicates that one end of C is connected to A, the other end of C is connected to B, and C is disposed in series in a path connecting A to B. “Path connecting A to B” indicates a path formed by a conductor that electrically connects A to B.

“Terminal” indicates a point at which a conductor in an element ends. When the impedance of a conductor between elements is sufficiently low, a terminal may be interpreted not only as a specific single point but also as any point on the conductor between the elements or the entire conductor.

“Pass band of filter” is defined as a part of a frequency spectrum transmitted by the filter and as a frequency band in which the output power is not attenuated by 3 dB or more from the maximum output power. That is, the high frequency end and the low frequency end of a pass band of a band pass filter correspond to the higher frequency and the lower frequency at two points at which the output power is attenuated by 3 dB from the maximum output power.

“Transmission band” refers to a frequency band used for transmission by a communication device, and “reception band” refers to a frequency band used for reception by a communication device. For example, in an FDD band, different frequency bands (e.g., an uplink band and a downlink band) are used as a transmission band and a reception band. Also, for example, in a time division duplex (TDD) band, the same frequency band is used as a transmission band and a reception band.

“Power class” is a classification of output power of user equipment defined by the maximum output power, and the allowed maximum output power increases as the value of the power class decreases. For example, in 3GPP, power classes 1, 1.5, 2, and 3 are defined. Specifically, in power class 1, the maximum output power is defined as 31 dBm. In power class 1.5, the maximum output power is defined as 29 dBm. In power class 2, the maximum output power is defined as 26 dBm. In power class 3, the maximum output power is defined as 23 dBm.

The maximum output power of a UE is defined as the maximum output power at the antenna end. The maximum output power of a UE is measured according to a method defined by, for example, 3GPP. For example, the maximum output power is measured by measuring radiated power of an antenna. Instead of measuring radiated power, a terminal may be provided near an antenna, and the maximum output power of the antenna may be measured with a measuring instrument (e.g., spectrum analyzer) connected to the terminal.

“Band supporting power class” means a frequency band that supports the power class and is defined by, for example, a standard. For example, in 3GPP, n2, n5, n8, n13, n25, n26, n28, n66, n71, and n85 are being considered as FDD bands for 5G NR supporting power class 2.

Terms such as “parallel” and “perpendicular” indicating relationships between elements, terms such as “rectangular” indicating shapes of elements, and numerical ranges do not only indicate their exact meanings but may also indicate substantially equivalent ranges that differ by, for example, about a few percent.

### First Embodiment

A first embodiment is described. A communication device 5 according to the present embodiment is usable to provide wireless connection. For example, the communication device 5 may be used for UEs, such as a mobile phone, a smartphone, a tablet computer, and a wearable device, in a cellular network (also referred to as a mobile network). As another example, the communication device 5 may be used to provide wireless connection for Internet of Things (IoT) sensor devices, medical/healthcare devices, vehicles, unmanned aerial vehicles (UAV) (commonly known as drones), and automated guided vehicles (AGV). As still another example, the communication device 5 may be used to provide wireless connection at wireless access points or wireless hotspots.

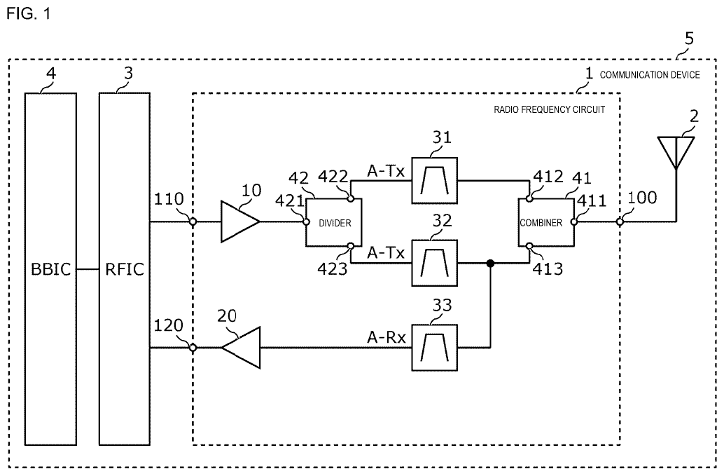

Circuit configurations of the communication device 5 and a radio frequency circuit 1 according to the present embodiment are described with reference to FIG. 1. FIG. 1 is a circuit diagram of the communication device 5 according to the present embodiment.

FIG. 1 illustrates an exemplary circuit configuration, and the communication device 5 and the radio frequency circuit 1 may be implemented by using any of various circuit implementations and circuit technologies. Accordingly, descriptions of the communication device 5 and the radio frequency circuit 1 provided below should not be interpreted restrictively.

### [1.1 Circuit Configuration of Communication Device 5]

First, a circuit configuration of the communication device 5 according to the present embodiment is described with reference to FIG. 1. The communication device 5 includes the radio frequency circuit 1, an antenna 2, a radio frequency integrated circuit (RFIC) 3, and a baseband integrated circuit (BBIC) 4.

The radio frequency circuit 1 can transmit radio frequency signals between the antenna 2 and the RFIC 3. The circuit configuration of the radio frequency circuit 1 is described later.

The antenna 2 is connected to an antenna connection terminal 100 of the radio frequency circuit 1. The antenna 2 can receive radio frequency signals from the radio frequency circuit 1 and transmit the radio frequency signals to the outside of the communication device 5. The antenna 2 can also receive radio frequency signals from the outside of the communication device 5 and output the radio frequency signals to the radio frequency circuit 1. Here, the antenna 2 does not have to be included in the communication device 5. Also, the communication device 5 may include one or more antennas in addition to the antenna 2.

The RFIC 3 is an example of a signal processing circuit that processes radio frequency signals. Specifically, the RFIC 3 can perform signal processing, such as up-converting, on a transmission signal input from the BBIC 4 and output a radio frequency transmission signal generated by the signal processing to the radio frequency circuit 1. Also, the RFIC 3 can perform signal processing, such as down-converting, on a radio frequency reception signal input via a reception path of the radio frequency circuit 1 and output a reception signal generated by the signal processing to the BBIC 4. Also, the RFIC 3 may include a control unit that controls, for example, switches and power amplifiers included in the radio frequency circuit 1. Some or all of the functions of the control unit of the RFIC 3 may be provided outside the RFIC 3 and included in, for example, the BBIC 4 or the radio frequency circuit 1.

The BBIC 4 is a baseband signal processing circuit that performs signal processing using a frequency band lower than that of radio frequency signals transmitted by the radio frequency circuit 1. Examples of signals processed by the BBIC 4 include an image signal for displaying an image and/or a voice signal for a call via a speaker. The BBIC 4 does not have to be included in the communication device 5.

### [1.2 Circuit Configuration of Radio Frequency Circuit 1]

Next, a circuit configuration of the radio frequency circuit 1 according to the present embodiment is described with reference to FIG. 1. The radio frequency circuit 1 includes a power amplifier 10, a low-noise amplifier 20, transmission filters 31 and 32, a reception filter 33, a combiner 41, a divider 42, an antenna connection terminal 100, a radio frequency input terminal 110, and a radio frequency output terminal 120. As used herein, the term “combining circuit” is used interchangeably with “combiner”, and refers to an electrical circuit network structurally configured to distribute, steer, or combine radio frequency power across a plurality of signal paths. The combining circuit may be implemented as a distributed-element circuit utilizing patterned transmission lines, microstrip lines, strip lines, or coplanar waveguides, or as a lumped-element circuit utilizing integrated or discrete passive components (such as capacitors, inductors, and resistors).

The antenna connection terminal 100 is an external connection terminal of the radio frequency circuit 1 and is connected to the antenna 2 outside the radio frequency circuit 1. The antenna connection terminal 100 is also connected to the combiner 41 inside the radio frequency circuit 1. With this configuration, the radio frequency circuit 1 can supply a transmission signal to the antenna 2 via the antenna connection terminal 100 and receive a reception signal from the antenna 2.

The radio frequency input terminal 110 is an external connection terminal of the radio frequency circuit 1 and is connected to the RFIC 3 outside the radio frequency circuit 1. The radio frequency input terminal 110 is also connected to the input end of the power amplifier 10 inside the radio frequency circuit 1. With this configuration, the radio frequency circuit 1 can supply a transmission signal received from the RFIC 3 via the radio frequency input terminal 110 to the power amplifier 10.

The radio frequency output terminal 120 is an external connection terminal of the radio frequency circuit 1 and is connected to the RFIC 3 outside the radio frequency circuit 1. The radio frequency output terminal 120 is also connected to the output end of the low-noise amplifier 20 inside the radio frequency circuit 1. With this configuration, the radio frequency circuit 1 can supply a reception signal amplified by the low-noise amplifier 20 to the RFIC 3 via the radio frequency output terminal 120.

The power amplifier 10 is connected between the radio frequency input terminal 110 and the transmission filters 31 and 32. Specifically, the input end of the power amplifier 10 is connected to the radio frequency input terminal 110. On the other hand, the output end of the power amplifier 10 is connected to the transmission filters 31 and 32 via the divider 42. The power amplifier 10 can amplify a transmission signal supplied from the RFIC 3 via the radio frequency input terminal 110 by using power supplied from a power supply (not shown).

The power amplifier 10 may be implemented by heterojunction bipolar transistors (HBT) and may be manufactured using a semiconductor material. For example, silicon germanium (SiGe) or gallium arsenide (GaAs) may be used as the semiconductor material. The amplifier transistors of the power amplifier 10 are not limited to HBTs. For example, the power amplifier 10 may be implemented by high electron mobility transistors (HEMT) or metal-semiconductor field effect transistors (MESFET). In this case, gallium nitride (GaN) or silicon carbide (SiC) may be used as the semiconductor material.

In the present embodiment, the power amplifier 10 supports a first power class (e.g., power class 2, 1.5, or 1) that is defined by a higher maximum output power. That is, the power amplifier 10 can amplify a transmission signal up to an output power sufficient to meet the maximum output power of a terminal defined by the first power class.

A part or the entirety of the power amplifier 10 does not have to be included in the radio frequency circuit 1. In this case, the part or entirety of the power amplifier 10 may be connected between the RFIC 3 and the radio frequency input terminal 110 or may be included in the RFIC 3.

The low-noise amplifier 20 is connected between the reception filter 33 and the radio frequency output terminal 120. Specifically, the input end of the low-noise amplifier 20 is connected to the reception filter 33. On the other hand, the output end of the low-noise amplifier 20 is connected to the radio frequency output terminal 120. The low-noise amplifier 20 can amplify a reception signal passed through the reception filter 33 by using power supplied from a power supply (not shown).

The low-noise amplifier 20 may be implemented by field-effect transistors (FET) and may be manufactured using a semiconductor material. Examples of semiconductor materials include silicon single crystal, gallium nitride (GaN), and silicon carbide (SiC). The amplifier transistors used for the low-noise amplifier 20 are not limited to FETs. For example, a part or the entirety of the low-noise amplifier 20 may be implemented by bipolar transistors.

A part or the entirety of the low-noise amplifier 20 does not have to be included in the radio frequency circuit 1. In this case, the part or entirety of the low-noise amplifier 20 may be connected between the radio frequency output terminal 120 and the RFIC 3 or may be included in the RFIC 3.

The transmission filter 31 is an example of a first transmission filter and has a pass band including a transmission band of a band A. The transmission filter 31 is connected between the antenna connection terminal 100 and the power amplifier 10. Specifically, the output end of the transmission filter 31 is connected to the antenna connection terminal 100 via the combiner 41. On the other hand, the input end of the transmission filter 31 is connected to the power amplifier 10 via the divider 42. In some embodiments, the transmission filter 31 only needs to have electric power handling capability corresponding to a second power class (e.g., power class 3) defined by a lower maximum output power and does not need to have electric power handling capability corresponding to the first power class (e.g., power class 2, 1.5, or 1) defined by a higher maximum output power. In other embodiments, the transmission filter 32 may operate with electric power handling parameters independent of the first power class.

The first power class allows a higher maximum output power than the second power class. The first power class is, for example, power class 2, power class 1.5, or power class 1. When a new power class is defined by a standard, the new power class may be used as the first power class.

The transmission filter 32 is an example of a second transmission filter and has a pass band including the transmission band of the band A. The transmission filter 32 is connected between the antenna connection terminal 100 and the power amplifier 10. Specifically, the output end of the transmission filter 32 is connected to the antenna connection terminal 100 via the combiner 41. On the other hand, the input end of the transmission filter 32 is connected to the power amplifier 10 via the divider 42. The transmission filter 32 only needs to have electric power handling capability corresponding to the second power class defined by a lower maximum output power and does not need to have electric power handling capability corresponding to the first power class defined by a higher maximum output power. Non-limiting examples of the combining circuit include a Wilkinson power combiner, a 90-degree hybrid coupler, a branch-line coupler, a directional coupler, or an impedance-matching multi-port network configured to aggregate power from parallel amplification structures. The term “coupler” as used herein, including in the terms “Wilkinson coupler” and “90-degree hybrid coupler,” refers to specific implementations of a combining circuit as defined above.

The reception filter 33 is an example of a third reception filter and has a pass band including a reception band of the band A. In this specification, the reception filter 33 is referred to as a “third reception filter” to correspond to its reference numeral 33, which follows the first transmission filter 31 and second transmission filter 32 in the numbering sequence. No first or second reception filter is required or implied. The reception filter 33 is connected between the antenna connection terminal 100 and the low-noise amplifier 20. Specifically, the input end of the reception filter 33 is connected to the antenna connection terminal 100 via the combiner 41. On the other hand, the output end of the reception filter 33 is connected to the low-noise amplifier 20.

The transmission filters 31 and 32 and the reception filter 33 are implemented by surface acoustic wave (SAW) filters, bulk acoustic wave (BAW) filters, LC resonant filters, dielectric resonator filters, or any combination of these filters. However, the transmission filters 31 and 32 and the reception filter 33 are not limited to these examples.

The band A is a frequency band used for a communication system that is constructed using radio access technology (RAT). The band A is predefined by, for example, a standardizing body (e.g., 3GPP or Institute of Electrical and Electronics Engineers (IEEE)). Examples of communication systems include a 5th Generation New Radio (5G NR) system, a Long Term Evolution (LTE) system, and a wireless local area network (WLAN) system.

The band A is an FDD band that supports the first power class. For example, the band A is 5G NR n2, n5, n8, n13, n25, n26, n28, n66, n71, or n85. However, the band A is not limited to these examples. As another example, an LTE band may be used as the band A.

The combiner 41 includes terminals 411, 412, and 413. The terminal 411 is an example of a first terminal and is connected to the antenna connection terminal 100. The terminal 412 is an example of a second terminal and is connected to the output end of the transmission filter 31. The terminal 413 is an example of a third terminal and is connected to the output end of the transmission filter 32 and the input end of the reception filter 33. The point at which the terminal 413 connects the output end of the transmission filter 32 and the input end of the reception filter 33 within the combiner 41 may also be referred to as a combining node.

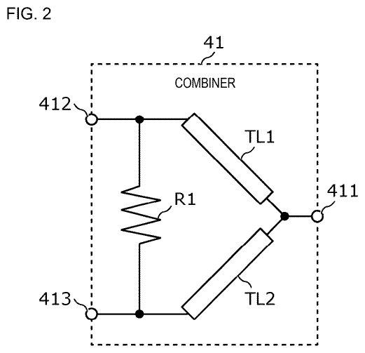

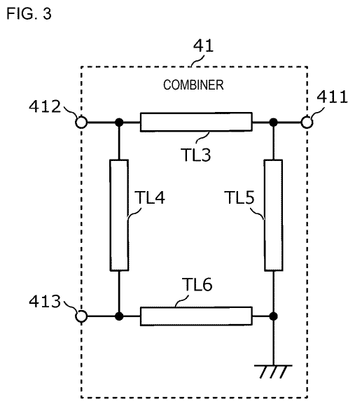

In the combiner 41, the isolation between the terminals 412 and 413 is sufficiently high in the transmission band and the reception band of the band A. This makes it possible to prevent a transmission signal passed through the filter 31 from leaking into the transmission and reception paths to which the filters 32 and 33 are connected. Also, the reception band impedance of the band A is sufficiently high when the transmission filter 31 is viewed from the terminal 411. The isolation between the terminals 412 and 413 may be sufficiently high in the transmission band and the reception band of the band A, e.g., the isolation provided by a Wilkinson coupler or a 90-degree hybrid coupler as described below with reference to FIGS. 2 and 3. This makes it possible to prevent a reception signal input from the antenna 2 from leaking into a transmission path to which the filter 31 is connected.

With the above configuration, a transmission signal in the band A input to the terminal 412 through the transmission filter 31 and a transmission signal in the band A input to the terminal 413 through the transmission filter 32 are combined by the combiner 41, and a resulting signal is output from the terminal 411 to the antenna 2 via the antenna connection terminal 100. Also, a reception signal input from the antenna 2 to the terminal 411 via the antenna connection terminal 100 is output from the terminal 413 to the reception filter 33.

Various types of combiners may be used as the combiner 41 depending on the phase difference between two input signals. Details of the circuit configuration of the combiner 41 are described later with reference to FIGS. 2 and 3.

The divider 42 includes terminals 421, 422, and 423. The terminal 421 is an example of a fourth terminal and is connected to the output end of the power amplifier 10. The terminal 422 is an example of a fifth terminal and is connected to the input end of the transmission filter 31. The terminal 423 is an example of a sixth terminal and is connected to the input end of the transmission filter 32. As used herein, the term “divider” is used interchangeably with “splitting circuit”, and refers to an electrical circuit network structurally configured to divide, separate, or distribute an incoming radio frequency signal into a plurality of output paths. The splitting circuit may be implemented as a distributed-element circuit utilizing patterned transmission lines, microstrip lines, strip lines, or coplanar waveguides, or as a lumped-element circuit utilizing integrated or discrete passive components (such as capacitors, inductors, and resistors). Non-limiting examples of the splitting circuit include a Wilkinson power splitter, a branch-line hybrid structure, a reactive power splitter, or an impedance-matched multi-port distribution network.

With this configuration, the divider 42 can divide a transmission signal in the band A supplied from the RFIC 3 via the radio frequency input terminal 110 into two signals and output the signals to the corresponding transmission filters 31 and 32. The circuit configuration of the divider 42 may be the same as that of the combiner 41.

The divider 42 may be either an equal divider or an unequal divider. In other words, the division ratio between the terminals 422 and 423 of the divider 42 may be 1:1 or M: N (M and N are natural numbers that are different from each other). For example, when M is greater than N, the average power of the transmission band of the band A at the terminal 413 of the combiner 41 is less than the average power of the transmission band of the band A at the terminal 412 of the combiner 41.

The average power of the transmission band of the band A at the terminal 412 and the average power of the transmission band of the band A at the terminal 413 may be obtained by measuring them simultaneously for the same period using instruments (e.g., spectrum analyzers) connected to the respective terminals 412 and 413.

### [1.3 Circuit Configurations of Combiner 41]

Next, circuit configurations of the combiner 41 according to the present embodiment are described with reference to FIGS. 2 and 3. FIGS. 2 and 3 are circuit diagrams of different examples of the combiner 41 according to the present embodiment.

FIGS. 2 and 3 illustrate exemplary circuit configurations, and the combiner 41 may be implemented by using any of various circuit implementations and circuit technologies. Therefore, the descriptions of the combiner 41 provided below should not be interpreted restrictively.

In the example of FIG. 2, the combiner 41 is a Wilkinson coupler and includes transmission lines TL1 and TL2 and a resistor R1. The transmission line TL1 is connected between the terminals 411 and 412 and implements a ¼ wavelength transmission line for the band A. The transmission line TL2 is connected between the terminals 411 and 413 and implements a ¼ wavelength transmission line for the band A. The resistor R1 is connected between the terminals 412 and 413 in parallel with the transmission lines TL1 and TL2. With this configuration, the combiner 41 can combine two in-phase transmission signals in the band A, which have respectively passed through the transmission filters 31 and 32, into a single signal. Each of the transmission lines TL1 and TL2 may include an inductor and/or a capacitor.

In the example of FIG. 3, the combiner 41 is a 90-degree hybrid coupler and includes transmission lines TL3, TL4, TL5, and TL6. Each of the transmission lines TL3 to TL6 implements a ¼ wavelength transmission line for the band A. The transmission line TL3 is connected between the terminals 411 and 412. The transmission line TL4 is connected between the terminals 412 and 413. The transmission lines TL5 and TL6 are connected in series between the terminals 411 and 413. With this configuration, the combiner 41 can combine two transmission signals in the band A, which have respectively passed through the transmission filters 31 and 32 and have a 90-degree phase difference, into a single signal. Each of the transmission lines TL3 to TL6 may include an inductor and/or a capacitor.

### [1.4 Summary]

As described above, the radio frequency circuit 1 according to the present embodiment includes the transmission filter 31 with a pass band including a transmission band of the band A, which is an FDD band, the transmission filter 32 with a pass band including the transmission band of the band A, the reception filter 33 with a pass band including a reception band of the band A, and the combiner 41 including the terminal 411 connected to the antenna connection terminal 100, the terminal 412 connected to the output end of the transmission filter 31, and the terminal 413 connected to the output end of the transmission filter 32 and the input end of the reception filter 33.

With this configuration, two transmission signals respectively passed through two transmission filters 31 and 32 can be combined by the combiner 41. This makes it possible to reduce the requirement for the electric power handling capability of each of the transmission filters 31 and 32, since each filter need individually support the full power of the combined transmission signal. Particularly, when a higher maximum output power is required, reducing the requirement for electric power handling capability of each of the transmission filters 31 and 32 offers a significant advantage. The reception filter 33 is connected to the terminal 413 of the combiner 41, which is also connected to the output end of the transmission filter 32. In embodiments where the average power at the terminal 413 is lower than the average power at the terminal 412, the reception filter 33 is thereby placed on a transmission path carrying a lower power level. This makes it possible to suppress the leakage of a transmission signal into the reception path and thereby makes it possible to suppress degradation of receiver performance. Furthermore, this makes it possible to reduce the requirement for electric power handling capability of the reception filter 33. Particularly, when a higher maximum output power is required, reducing the rather power handling capability of the reception filter 33 offers a significant advantage.

Also, for example, in the radio frequency circuit 1 of the present embodiment, the combiner 41 may be a Wilkinson coupler.

Using a Wilkinson coupler as the combiner 41 makes it possible to ensure isolation between the terminals 412 and 413. This makes it possible to prevent a transmission signal passed through the transmission filter 31 from leaking into the reception filter 33 via the combiner 41 and thereby makes it possible to suppress degradation of receiver performance.

Also, for example, in the radio frequency circuit 1 of the present embodiment, the combiner 41 may be a 90-degree hybrid coupler.

Using a 90-degree hybrid coupler as the combiner 41 makes it possible to ensure isolation between the terminals 412 and 413. This makes it possible to prevent a transmission signal passed through the transmission filter 31 from leaking into the reception filter 33 via the combiner 41 and thereby makes it possible to suppress degradation of receiver performance.

Furthermore, the radio frequency circuit 1 of the present embodiment may include the power amplifier 10 and the divider 42 that includes the terminal 421 connected to the output end of the power amplifier 10, the terminal 422 connected to the input end of the transmission filter 31, and the terminal 423 connected to the input end of the transmission filter 32.

This configuration makes it possible to amplify a transmission signal with one power amplifier 10, to suppress an increase in the number of power amplifiers, and to contribute to the miniaturization of the communication device 5.

Also, for example, in the radio frequency circuit 1 of the present embodiment, the average power of the transmission band of the band A at the terminal 413 may be lower than the average power of the transmission band of the band A at the terminal 412.

In this case, the reception filter 33 is connected to the terminal 413 to which a transmission signal with a lower power level is input rather than to the terminal 412 to which a transmission signal with a higher power level is input. This makes it possible to further suppress the leakage of a transmission signal into the reception path and thereby makes it possible to further suppress degradation of receiver performance.

Also, for example, in the radio frequency circuit 1 of the present embodiment, the band A supports the first power class that is defined by a maximum output power higher than the maximum output power of power class 3.

This means that a maximum output power higher than 23 dBm, which is the maximum output power of conventional power class 3, is required. Therefore, reducing the requirement for electric power handling capability of the transmission filters 31 and 32 and the reception filter 33 offers a significant advantage.

The communication device 5 according to the present embodiment includes the RFIC 3 configured to process radio frequency signals and the radio frequency circuit 1 configured to transmit radio frequency signals between the RFIC 3 and the antenna 2.

With this configuration, the communication device 5 can provide the same effects as those provided by the radio frequency circuit 1.

### Second Embodiment

Next, a second embodiment is described. The present embodiment differs from the first embodiment mainly in that each of a filter and a power amplifier is divided into two units. Below, differences between the first embodiment and the present embodiment are mainly described with reference to the drawings.

### [2.1 Circuit Configuration of Radio Frequency Circuit 1A]

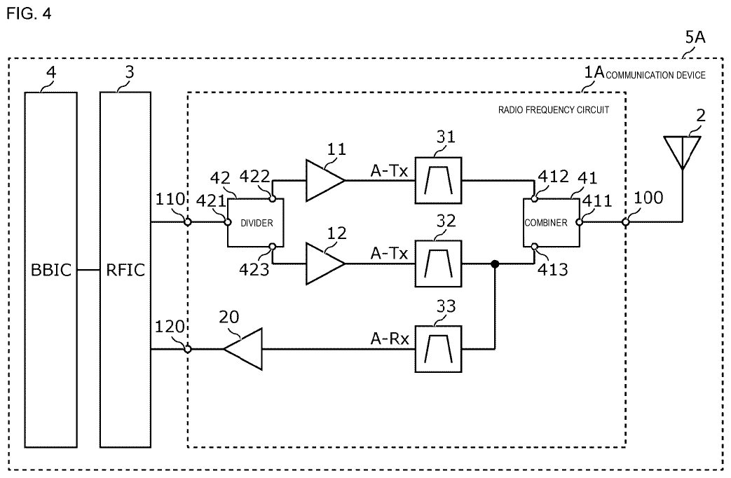

A circuit configuration of a radio frequency circuit 1A according to the present embodiment is described with reference to FIG. 4. A communication device 5A of the present embodiment is substantially the same as the communication device 5 of the first embodiment except that the radio frequency circuit 1 is replaced with the radio frequency circuit 1A. Therefore, descriptions of other components of the communication device 5A are omitted.

FIG. 4 is a circuit diagram of the communication device 5A according to the present embodiment. FIG. 4 illustrates an exemplary circuit configuration, and the communication device 5A and the radio frequency circuit 1A may be implemented by using any of various circuit implementations and circuit technologies. Accordingly, descriptions of the radio frequency circuit 1A provided below should not be interpreted restrictively.

The radio frequency circuit 1A includes power amplifiers 11 and 12, a low-noise amplifier 20, transmission filters 31 and 32, a reception filter 33, a combiner 41, a divider 42, an antenna connection terminal 100, a radio frequency input terminal 110, and a radio frequency output terminal 120.

The power amplifier 11 is an example of a first power amplifier and is connected between the radio frequency input terminal 110 and the transmission filter 31. Specifically, the input end of the power amplifier 11 is connected to the radio frequency input terminal 110 via the divider 42. On the other hand, the output end of the power amplifier 11 is connected to the transmission filter 31. The power amplifier 11 can amplify a transmission signal supplied from the RFIC 3 via the radio frequency input terminal 110 and the divider 42 by using power supplied from a power supply (not shown).

The power amplifier 12 is an example of a second power amplifier and is connected between the radio frequency input terminal 110 and the transmission filter 32. Specifically, the input end of the power amplifier 12 is connected to the radio frequency input terminal 110 via the divider 42. On the other hand, the output end of the power amplifier 12 is connected to the transmission filter 32. The power amplifier 12 can amplify a transmission signal supplied from the RFIC 3 via the radio frequency input terminal 110 and the divider 42 by using power supplied from a power supply (not shown).

In the present embodiment, each of the power amplifiers 11 and 12 supports a second power class (e.g., power class 3) that is defined by a lower maximum output power. That is, each of the power amplifiers 11 and 12 does not have to support a first power class (e.g., power class 2, 1.5, or 1) that is defined by a higher maximum output power. Even in this case, the radio frequency circuit 1A can support the first power class by combining two transmission signals that are respectively amplified by two power amplifiers 11 and 12.

### [2.2 Summary]

As described above, the radio frequency circuit 1A of the present embodiment may further include the power amplifier 11 connected to the input end of the transmission filter 31 and the power amplifier 12 connected to the input end of the transmission filter 32.

With this configuration, two transmission signals respectively amplified by two power amplifiers 11 and 12 can be combined by the combiner 41. This eliminates the need for each of the power amplifiers 11 and 12 to support the power of a transmission signal obtained by combining two transmission signals and thereby makes it possible to reduce the requirement for the output power of each of the power amplifiers 11 and 12.

Also, for example, the radio frequency circuit 1A of the present embodiment may include the divider 42 that includes a terminal 421 connected to the radio frequency input terminal 110, a terminal 422 connected to the input end of the power amplifier 11, and a terminal 423 connected to the input end of the power amplifier 12.

With this configuration, the radio frequency circuit 1A can divide one transmission signal into two transmission signals. This in turn makes it possible to suppress an increase in the number of radio frequency input terminals 110 connected to the RFIC 3.

### Variation of Second Embodiment

In the second embodiment, the divider 42 does not have to be included in the radio frequency circuit 1A and may be included in, for example, the RFIC 3. A radio frequency circuit 1B according to a variation of the second embodiment is described with reference to the drawing.

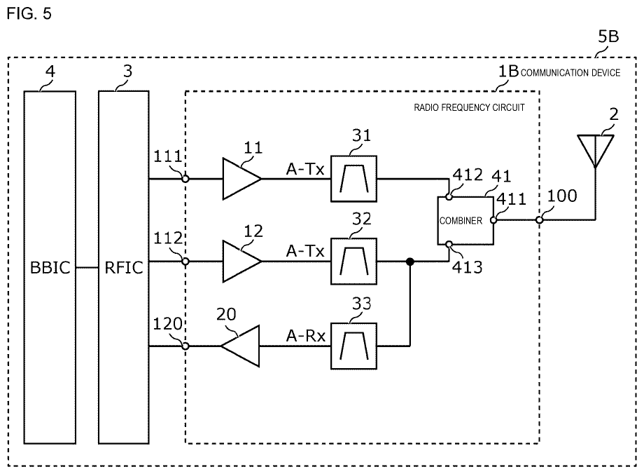

A circuit configuration of the radio frequency circuit 1B according to the present variation is described with reference to FIG. 5. A communication device 5B of the present variation is substantially the same as the communication device 5 of the first embodiment except that the radio frequency circuit 1 is replaced with the radio frequency circuit 1B. Therefore, descriptions of other components of the communication device 5B are omitted.

The radio frequency circuit 1B includes power amplifiers 11 and 12, a low-noise amplifier 20, transmission filters 31 and 32, a reception filter 33, a combiner 41, an antenna connection terminal 100, radio frequency input terminals 111 and 112, and a radio frequency output terminal 120.

Each of the radio frequency input terminals 111 and 112 is an external connection terminal of the radio frequency circuit 1B and is connected to the RFIC 3 outside the radio frequency circuit 1B. The radio frequency input terminals 111 and 112 are also respectively connected to the power amplifiers 11 and 12 inside the radio frequency circuit 1B. With this configuration, in the radio frequency circuit 1B, a transmission signal received from the RFIC 3 via the radio frequency input terminal 111 can be supplied to the power amplifier 11, and a transmission signal received from the RFIC 3 via the radio frequency input terminal 112 can be supplied to the power amplifier 12.

### Third Embodiment

Next, a third embodiment is described. The present embodiment mainly differs from the first and second embodiments in that the combiner 41 can be bypassed. Below, differences between the present embodiment and the first and second embodiments are mainly described with reference to the drawings.

### [3.1 Circuit Configuration of Radio Frequency Circuit 1C]

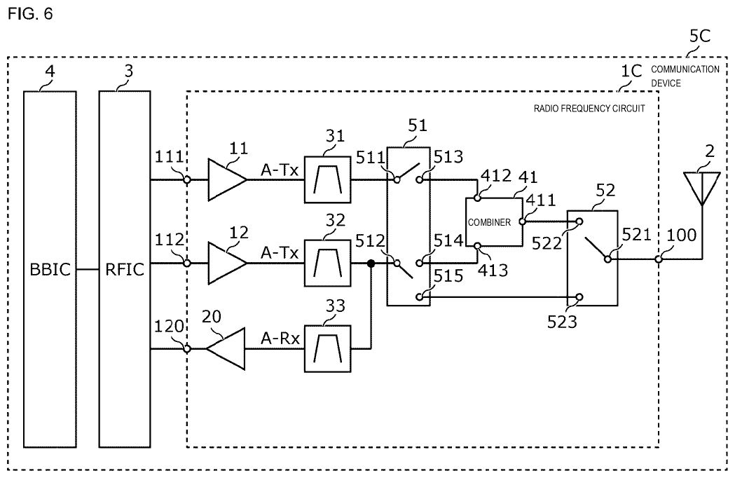

A circuit configuration of a radio frequency circuit 1C according to the present embodiment is described with reference to FIG. 6. A communication device 5C of the present embodiment is substantially the same as the communication device 5 of the first embodiment except that the radio frequency circuit 1 is replaced with a radio frequency circuit 1C. Therefore, descriptions of other components of the communication device 5C are omitted.

FIG. 6 is a circuit diagram of the communication device 5C according to the present embodiment. FIG. 6 illustrates an exemplary circuit configuration, and the communication device 5C and the radio frequency circuit 1C may be implemented by using any of various circuit implementations and circuit technologies. Accordingly, descriptions of the radio frequency circuit 1C provided below should not be interpreted restrictively.

The radio frequency circuit 1C includes power amplifiers 11 and 12, a low-noise amplifier 20, transmission filters 31 and 32, a reception filter 33, a combiner 41, switch circuits 51 and 52, an antenna connection terminal 100, radio frequency input terminals 111 and 112, and a radio frequency output terminal 120.

The switch circuit 51 is an example of a first switch circuit and includes terminals 511, 512, 513, 514, and 515. The terminal 511 is an example of a seventh terminal and is connected to the output end of the transmission filter 31. The terminal 512 is an example of an eighth terminal and is connected to the output end of the transmission filter 32 and the input end of the reception filter 33. The terminal 513 is an example of a ninth terminal and is connected to a terminal 412 of the combiner 41. The terminal 514 is an example of a tenth terminal and is connected to a terminal 413 of the combiner 41. The terminal 515 is an example of an eleventh terminal and is switchably connected to the antenna connection terminal 100 via the switch circuit 52.

In this connection configuration, the switch circuit 51 can connect the terminal 511 to the terminal 513 and exclusively connect the terminal 512 to one of the terminals 514 and 515 based on a control signal from, for example, the RFIC 3. For example, the switch circuit 51 is implemented by a combination of a single-pole single-throw (SPST) switch circuit and a single-pole double-throw (SPDT) switch circuit.

The switch circuit 52 is an example of a second switch circuit and includes terminals 521, 522, and 523. The terminal 521 is an example of a twelfth terminal and is connected to the antenna connection terminal 100. The terminal 522 is an example of a thirteenth terminal and is connected to a terminal 411 of the combiner 41. The terminal 523 is an example of fourteenth terminal and is connected to the terminal 515 of the switch circuit 51.

With this connection configuration, the switch circuit 52 can exclusively connect the terminal 521 to one of the terminals 522 and 523 based on a control signal from, for example, the RFIC 3. The switch circuit 52 is implemented by, for example, an SPDT switch circuit.

The switch circuit 52 does not have to be included in the radio frequency circuit 1C. In this case, the terminal 515 of the switch circuit 51 and the terminal 411 of the combiner 41 may be directly connected to the antenna connection terminal 100.

### [3.2 Communication Modes of Communication Device 5C and Radio Frequency Circuit 1C]

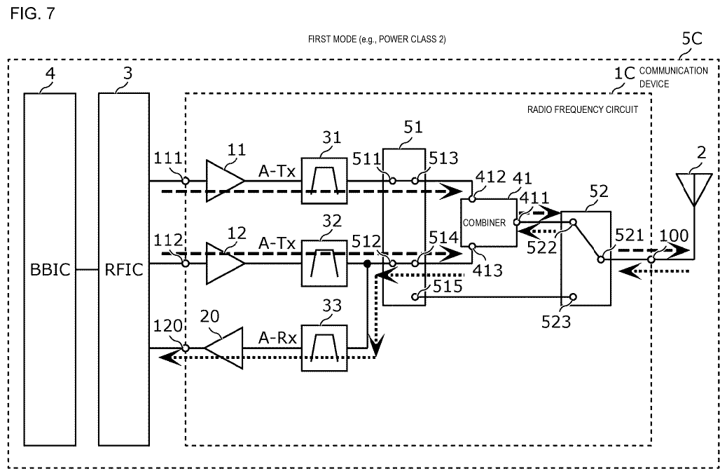

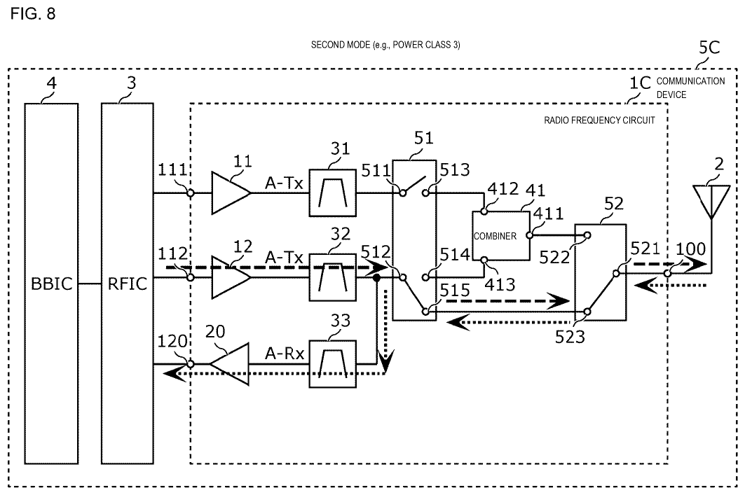

Next, two communication modes of the communication device 5C and the radio frequency circuit 1C are described with reference to FIGS. 7 and 8. In FIGS. 7 and 8, dashed arrows represent a transmission path and a reception path.

### [3.2.1 First Mode]

First, a first mode is described with reference to FIG. 7. FIG. 7 is a diagram illustrating a transmission path and a reception path in the first mode of the radio frequency circuit 1C according to the present embodiment.

The first mode is a control mode that is used when the first power class is applied to the band A. In the first mode, as illustrated in FIG. 7, two transmission filters 31 and 32 for the band A are connected to the antenna connection terminal 100 via the combiner 41. Specifically, the switch circuit 51 connects the terminal 511 to the terminal 513, connects the terminal 512 to the terminal 514, and does not connect the terminal 512 to the terminal 515. Also, the switch circuit 52 connects the terminal 521 to the terminal 522 and does not connect the terminal 521 to the terminal 523.

As a result, a transmission signal in the band A supplied from the RFIC 3 via the radio frequency input terminal 111 is transmitted to the terminal 412 of the combiner 41 via the power amplifier 11, the transmission filter 31, and the switch circuit 51. Also, a transmission signal in the band A supplied from the RFIC 3 via the radio frequency input terminal 112 is transmitted to the terminal 413 of the combiner 41 via the power amplifier 12, the transmission filter 32, and the switch circuit 51. Then, the two transmission signals in the band A input to the terminals 412 and 413 of the combiner 41 are combined into one signal, and the signal is transmitted to the antenna connection terminal 100 via the switch circuit 52.

On the other hand, a reception signal in the band A supplied from the antenna 2 via the antenna connection terminal 100 is transmitted to the radio frequency output terminal 120 via the switch circuit 52, the combiner 41, the switch circuit 51, the reception filter 33, and the low-noise amplifier 20.

### [3.2.2 Second Mode]

Next, a second mode is described with reference to FIG. 8. FIG. 8 is a diagram illustrating a transmission path and a reception path in the second mode of the radio frequency circuit 1C according to the present embodiment.

The second mode is a control mode that is used when the second power class is applied to the band A. In the second mode, as illustrated in FIG. 8, only one of the two transmission filters 31 and 32 for the band A (the transmission filter 32 in FIG. 8) is connected to the antenna connection terminal 100 bypassing the combiner 41. Specifically, the switch circuit 51 does not connect the terminal 511 to the terminal 513, connects the terminal 512 to the terminal 515, and does not connect the terminal 512 to the terminal 514. Also, the switch circuit 52 connects the terminal 521 to the terminal 523 and does not connect the terminal 521 to the terminal 522.

As a result, a transmission signal in the band A supplied from the RFIC 3 via the radio frequency input terminal 112 is transmitted to the antenna connection terminal 100 via the power amplifier 12, the transmission filter 32, and the switch circuits 51 and 52.

On the other hand, a reception signal in the band A supplied from the antenna 2 via the antenna connection terminal 100 is transmitted to the radio frequency output terminal 120 via the switch circuits 52 and 51, the reception filter 33, and the low-noise amplifier 20.

In the above example, the mode applied to the radio frequency circuit 1C is selected based on the power class. However, the present disclosure is not limited to this example. As another example, the mode applied to the radio frequency circuit 1C may be selected based on signal quality and/or power efficiency required for transmission. Specifically, when signal quality is prioritized in transmission in the band A, the first mode may be used; and when power efficiency is prioritized in transmission in the band A, the second mode may be used. Also, the mode applied to the radio frequency circuit 1C may be selected based on a combination of a power class and at least one of signal quality and power efficiency. Specifically, when the first power class is applied to the band A, the first mode is used; and when the second power class is applied to the band A and power efficiency is prioritized, the second mode is used. Here, even when the second power class is applied to the band A, the first mode may be used when signal quality is prioritized.

### [3.3 Summary]

As described above, the radio frequency circuit 1C according to the present embodiment may further include the switch circuit 51. The switch circuit 51 may include the terminal 511 connected to the output end of the transmission filter 31, the terminal 512 connected to the output end of the transmission filter 32 and the input end of the reception filter 33, the terminal 513 connected to the terminal 412 of the combiner 41, the terminal 514 connected to the terminal 413 of the combiner 41, and the terminal 515 connected to the antenna connection terminal 100.

With this configuration, the switch circuit 51 can switch between a transmission path connecting two transmission filters 31 and 32 to the antenna connection terminal 100 via the combiner 41 and a transmission path connecting the transmission filter 32 to the antenna connection terminal 100 bypassing the combiner 41. Selecting the transmission path connecting two transmission filters 31 and 32 to the antenna connection terminal 100 via the combiner 41 makes it possible to reduce the power of transmission signals that pass through the respective transmission filters 31 and 32. Selecting the transmission path connecting the transmission filter 32 to the antenna connection terminal 100 bypassing the combiner 41 makes it possible to suppress the loss of a transmission signal that passes through the transmission filter 32.

Also, for example, the radio frequency circuit 1C according to the present embodiment may further include the switch circuit 52. The switch circuit 52 may include the terminal 521 connected to the antenna connection terminal 100, the terminal 522 connected to the terminal 411 of the combiner 41, and the terminal 523 connected to the terminal 515 of the switch circuit 51.

With this configuration, the switch circuit 52 can also switch between the transmission path connecting two transmission filters 31 and 32 to the antenna connection terminal 100 via the combiner 41 and the transmission path connecting the transmission filter 32 to the antenna connection terminal 100 bypassing the combiner 41. This in turn makes it possible to improve the isolation between the two transmission paths.

Also, for example, the radio frequency circuit 1C of the present embodiment may have the first mode and the second mode. In the first mode, (i) the switch circuit 51 may connect the terminal 511 to the terminal 513 and connect the terminal 512 to the terminal 514, and (ii) the switch circuit 52 may connect the terminal 521 to the terminal 522. In the second mode, (i) the switch circuit 51 may connect the terminal 512 to the terminal 515, and (ii) the switch circuit 52 may connect the terminal 521 to the terminal 523.

With this configuration, when the first mode is used, two transmission filters 31 and 32 are connected to the antenna connection terminal 100 via the combiner 41; and when the second mode is used, the transmission filter 32 is connected to the antenna connection terminal 100 bypassing the combiner 41.

Also, for example, in the radio frequency circuit 1C of the present embodiment, the first mode may be used when the first power class is applied to the band A; and the second mode may be used when the second power class, which is defined by a maximum output power lower than the maximum output power of the first power class, is applied to the band A.

Accordingly, using the first mode in a higher power class (i.e., first power class) makes it possible to reduce the maximum power of transmission signals in the band A that respectively pass through the transmission filters 31 and 32 and thereby makes it possible to reduce electric power handling capability required for each of the transmission filters 31 and 32. Also, in a lower power class (i.e., second power class), it is possible to prevent signal loss caused by the combiner 41 and thereby improve power efficiency.

### Other Embodiments

Radio frequency circuits and communication devices according to embodiments of the present disclosure are described above. However, the present disclosure is not limited to the radio frequency circuits and the communication devices according to the above described embodiments. The present disclosure may also include other embodiments implemented by combining components in the above embodiments, variations obtained by making various modifications conceivable by a person skilled in the art to the embodiments without departing from the spirit of the present disclosure, and various devices including the radio frequency circuits.

For example, in the circuit configurations of various circuits according to the above embodiments, additional circuit elements and wires may be inserted in paths connecting the circuit elements and the signal paths illustrated in the drawings. For example, an impedance matching circuit may be inserted between an amplifier and a filter and/or between a filter and a combiner. As a non-limiting example, the impedance matching circuit may be implemented by an inductor and/or a capacitor.

In the above embodiments, a radio frequency circuit may include a filter and/or an amplifier for a band different from the band A. For example, a reception filter with a pass band including a reception band of a band B different from the band A may be connected to the terminal 413 of the combiner 41. For example, a fourth reception filter with a pass band including a reception band of a band B different from the band A may be connected to the terminal 413 of the combiner 41.

Features of the radio frequency circuits and the communication devices according to the above embodiments are described below.
<1>

A radio frequency circuit includes a first transmission filter with a pass band including a transmission band of an FDD band; a second transmission filter with a pass band including the transmission band of the FDD band; a third reception filter with a pass band including a reception band of the FDD band; and a combiner including a first terminal connected to an antenna connection terminal, a second terminal connected to the output end of the first transmission filter, and a third terminal connected to the output end of the second transmission filter and the input end of the third reception filter.
<2>

In the radio frequency circuit described in <1>, the combiner is a Wilkinson coupler.
<3>

In the radio frequency circuit described in <1>, the combiner is a 90-degree hybrid coupler.
<4>

The radio frequency circuit described in any one of <1> to <3> further includes a power amplifier; and a divider including a fourth terminal connected to the output end of the power amplifier, a fifth terminal connected to the input end of the first transmission filter, and a sixth terminal connected to the input end of the second transmission filter.
<5>

The radio frequency circuit described in any one of <1> to <3> further includes a first power amplifier connected to the input end of the first transmission filter and a second power amplifier connected to the input end of the second transmission filter.
<6>

The radio frequency circuit described in <5> further includes a divider including a fourth terminal connected to a radio frequency input terminal, a fifth terminal connected to the input end of the first power amplifier, and a sixth terminal connected to the input end of the second power amplifier.
<7>

In the radio frequency circuit described in any one of <1> to <6>, the average power of the transmission band of the FDD band at the third terminal is less than the average power of the transmission band of the FDD band at the second terminal.
<8>

The radio frequency circuit described in any one of <1> to <7> further includes a first switch circuit. The first switch circuit includes a seventh terminal connected to the output end of the first transmission filter, an eighth terminal connected to the output end of the second transmission filter and the input end of the third reception filter, a ninth terminal connected to the second terminal of the combiner, a tenth terminal connected to the third terminal of the combiner, and an eleventh terminal connected to the antenna connection terminal.
<9>

The radio frequency circuit described in <8> further includes a second switch circuit. The second switch circuit includes a twelfth terminal connected to the antenna connection terminal, a thirteenth terminal connected to the first terminal of the combiner, and a fourteenth terminal connected to the eleventh terminal of the first switch circuit.
<10>

In the radio frequency circuit described in <9>, the radio frequency circuit has a first mode and a second mode. In the first mode, (i) the first switch circuit connects the seventh terminal to the ninth terminal and connects the eighth terminal to the tenth terminal, and (ii) the second switch circuit connects the twelfth terminal to the thirteenth terminal. In the second mode, (i) the first switch circuit connects the eighth terminal to the eleventh terminal, and (ii) the second switch circuit connects the twelfth terminal to the fourteenth terminal.
<11>

In the radio frequency circuit described in <10>, the first mode is used when a first power class is applied to the FDD band, and the second mode is used when a second power class, which is defined by a maximum output power lower than the maximum output power of the first power class, is applied to the FDD band.
<12>

In the radio frequency circuit described in any one of <1> to <11>, the FDD band supports a first power class defined by a maximum output power higher than the maximum output power of power class 3.
<13>

A communication device includes a signal processing circuit that processes a radio frequency signal and the radio frequency circuit described in any one of <1> to <11> that transmits the radio frequency signal between the signal processing circuit and an antenna.

### INDUSTRIAL APPLICABILITY

The present disclosure can be widely used for communication devices, such as mobile phones, as a radio frequency circuit disposed in a front-end unit.

### REFERENCE SIGNS LIST

1, 1A, 1B, 1C radio frequency circuit
2 antenna
3 RFIC
4 BBIC
5, 5A, 5B, 5C communication device
10, 11, 12 power amplifier
20 low-noise amplifier
31, 32 transmission filter
33 reception filter
41 combiner
42 divider
51, 52 switch circuit
100 antenna connection terminal
110, 111, 112 radio frequency input terminal
120 radio frequency output terminal
411, 412, 413, 421, 422, 423, 511, 512, 513, 514, 515,
521, 522, 523 terminal
R1 resistor
TL1, TL2, TL3, TL4, TL5, TL6 transmission line

1. A radio frequency circuit comprising:
a first transmission filter having a first pass band that includes an uplink transmission band of a frequency division duplex (FDD) band;
a second transmission filter having a second pass band that includes the uplink transmission band of the FDD band;
a reception filter having a third pass band that includes a downlink reception band of the FDD band; and
a combining circuit including a first terminal connected to an antenna connection terminal, a second terminal connected to an output end of the first transmission filter, and a third terminal connected to an output end of the second transmission filter and an input end of the reception filter.

2. The radio frequency circuit according to claim 1, wherein
the combining circuit is a Wilkinson coupler.

3. The radio frequency circuit according to claim 1, wherein
the combining circuit is a 90-degree hybrid coupler.

4. The radio frequency circuit according to claim 1, further comprising:
a power amplifier; and
a splitting circuit including a fourth terminal connected to an output end of the power amplifier, a fifth terminal connected to an input end of the first transmission filter, and a sixth terminal connected to an input end of the second transmission filter.

5. The radio frequency circuit according to claim 1, further comprising:
a first power amplifier connected to an input end of the first transmission filter; and
a second power amplifier connected to an input end of the second transmission filter.

6. The radio frequency circuit according to claim 5, further comprising:
a splitting circuit including a fourth terminal connected to a radio frequency input terminal, a fifth terminal connected to an input end of the first power amplifier, and a sixth terminal connected to an input end of the second power amplifier.

7. The radio frequency circuit according to claim 1, wherein
the radio frequency circuit is configured such that an average power of the transmission band of the FDD band at the third terminal is less than an average power of the transmission band of the FDD band at the second terminal.

8. The radio frequency circuit according to claim 1, further comprising:
a first switch circuit between the transmission filters and the combining circuit,
the first switch circuit including:
a seventh terminal connected to the output end of the first transmission filter,
an eighth terminal connected to the output end of the second transmission filter and the input end of the reception filter,
a ninth terminal connected to the second terminal of the combining circuit,
a tenth terminal connected to the third terminal of the combining circuit, and
an eleventh terminal connected to the antenna connection terminal.

9. The radio frequency circuit according to claim 8, further comprising:
a second switch circuit, wherein
the second switch circuit includes
a twelfth terminal connected to the antenna connection terminal,
a thirteenth terminal connected to the first terminal of the combining circuit, and
a fourteenth terminal connected to the eleventh terminal of the first switch circuit.

10. The radio frequency circuit according to claim 9, wherein
the radio frequency circuit has a first mode and a second mode;
in the first mode, (i) the first switch circuit connects the seventh terminal to the ninth terminal and connects the eighth terminal to the tenth terminal, and (ii) the second switch circuit connects the twelfth terminal to the thirteenth terminal; and
in the second mode, (i) the first switch circuit connects the eighth terminal to the eleventh terminal, and (ii) the second switch circuit connects the twelfth terminal to the fourteenth terminal.

11. The radio frequency circuit according to claim 10, wherein
the first mode is used when a first power class is applied to the FDD band, and
the second mode is used when a second power class, which is defined by a maximum output power lower than a maximum output power of the first power class, is applied to the FDD band.

12. The radio frequency circuit according to claim 1, wherein
the FDD band supports a first power class defined by a maximum output power higher than a maximum output power of power class 3.

13. The radio frequency circuit according to claim 1, further comprising a fourth reception filter having a pass band including a reception band of a second FDD band different from the FDD band, wherein an input end of the fourth reception filter is connected to the third terminal of the combining circuit.

14. A communication system comprising:
a signal processing integrated circuit configured to process radio frequency signals; and
a radio frequency frontend circuit coupled between the signal processing integrated circuit and an antenna connection terminal, the radio frequency frontend circuit including:
a first transmission path containing a first band-pass filter configured to pass a transmission band of a frequency division duplex (FDD) band;
a second transmission path containing a second band-pass filter configured to pass the transmission band of the FDD band;
a reception path containing a reception band-pass filter configured to pass a reception band of the FDD band; and
a combining circuit having a first terminal routed toward the antenna connection terminal, a second terminal terminating the first transmission path, and a third terminal connected to an output of the second band-pass filter and an input of the reception band-pass filter, such that the reception path shares a combining circuit with the second transmission path.

15. The communication system according to claim 14, wherein the combining circuit is configured to combine power from separate signals traveling concurrently along the first transmission path and the second transmission path.

16. The communication system according to claim 14, further comprising control circuitry configured to selectively route signals past the combining circuit to bypass signal combining when operating below a predetermined power threshold.

17. The communication system according to claim 14, wherein the signal processing integrated circuit includes a radio frequency integrated circuit (RFIC) and a baseband integrated circuit (BBIC).

18. A method of operating a radio frequency circuit, the method comprising:
filtering a first portion of a transmission signal through a first transmission filter having a pass band matching a frequency division duplex (FDD) transmission band;
filtering a second portion of the transmission signal through a second transmission filter having a pass band matching the FDD transmission band;
combining the filtered first portion and the filtered second portion at a combining node to generate a combined transmission signal directed to an antenna node; and
routing an incoming reception signal from the antenna node to a reception filter through the same combining node at which the filtered second portion is received from the second transmission filter.

19. The method according to claim 18, further comprising switching a switch circuit to disconnect the first transmission filter and the second transmission filter from the combining node and to connect the second transmission filter directly to the antenna, bypassing the combining node, such that the reception signal is routed from the antenna to the reception filter without passing through the combining node.

20. The method according to claim 19, wherein:
combining and routing are performed when a first power class is applied to the FDD band; and
switching is performed when a second power class, defined by a maximum output power lower than a maximum output power of the first power class, is applied to the FDD band.
